(19) United States
(12) Patent Application Publication
(10) Pub. No.: US 2026/0055508 A1
(43) Pub. Date: Feb. 26, 2026

(54) SHADOW FRAME HAVING SEPARABLE CROSSBEAM

(71) Applicant: Applied Materials, Inc., Santa Clara, CA (US)

(72) Inventors: Takayuki MATSUMOTO, Cupertino, CA (US); Robin L. TINER, Santa Cruz, CA (US); Gaku FURUTA, Sunnyvale, CA (US); Wen-Hao WU, San Jose, CA (US)

(21) Appl. No.: 19/307,873

(22) Filed: Aug. 22, 2025

Related U.S. Application Data
(60) Provisional application No. 63/686,017, filed on Aug. 22, 2024.

(51) Int. Cl. C23C 16/458

(52) U.S. Cl. CPC C23C 16/4585

(57) ABSTRACT

The present disclose generally relates to a shadow frame having a cross center beam for improved processing ability, manufacturability, and tolerance. In one embodiment, a shadow frame comprises a center beam with one or more surfaces for receiving one or more fastening mechanisms, a shadow frame body coupled to the center beam, the shadow frame body having a top surface, a bottom surface, and a plurality of side surfaces, the top surface having a cavity therein for receiving the center beam, and one or more fastening mechanisms coupled with the center beam and the shadow frame body.

### CROSS-REFERENCE TO RELATED APPLICATIONS

This application claims benefit of U.S. provisional patent application Ser. No. 63/686,017, filed Aug. 22, 2024, which is herein incorporated by reference.

### BACKGROUND

### Field

Embodiments of the present disclosure generally relate to a shadow frame used for substrate processing.

### Description of the Related Art

Substrate processing chambers, such as plasma-enhanced chemical vapor deposition (PECVD) processing chambers, may be employed to deposit thin films on substrates to form electronic devices. Generally, the layer deposition may be provided in static or in dynamic coating processes. During coating processes, a substrate is positioned on a substrate supporting platform to be coated within a coating chamber. The substrate is secured to a support platform within a deposition chamber by clamp springs or a clamp frame while being coated. By applying these processes, single layers or multi-layer systems are deposited on glass substrates to produce coated panels, display screens, OLED (organic light emitting diode) panels, thermally insulating glass panels and so forth.

When depositing material onto a substrate during processing, material may deposit onto other areas of the processing chamber as well. In order to prevent deposition of particles on the edge or on the underside of the substrate, a substrate holder may include an edge exclusion or shadow frame for preventing processing of a perimeter portion of the (upper) substrate surface. By providing a shadow frame, processing gases and plasma are prevented from reaching the edge and backside of the substrate.

The dimensions of the shadow frame are adapted to the size of the substrate. However, for large sized substrates, the correspondingly large shadow frames often face issues related to substrate processing (e.g., deformity), manufacturability, and tight tolerances (e.g., flatness).

Therefore, there is a need in the art for a shadow frame with one or more of improved processing ability, manufacturability, and tolerance.

### SUMMARY

The present disclose generally relates to a shadow frame having a cross center beam for improved processing ability, manufacturability, and tolerance. In one embodiment, a shadow frame comprises a center beam with one or more surfaces for receiving one or more fastening mechanisms, a shadow frame body coupled to the center beam, the shadow frame body having a top surface, a bottom surface, and a plurality of side surfaces, the top surface having a cavity therein for receiving the center beam, and one or more fastening mechanisms coupled with the center beam and the shadow frame body.

In one embodiment, a shadow frame including a center beam with one or more surfaces for receiving one or more fastening mechanisms; a shadow frame body coupled to the center beam, the shadow frame body having a top surface, a bottom surface, and a plurality of side surfaces, a cavity is disposed in the top surface of the shadow frame body for receiving the center beam; and one or more fastening mechanisms coupled with the center beam and the shadow frame body.

In another embodiment, a shadow frame including a center beam with one or more surfaces for receiving one or more fastening mechanisms; a shadow frame body coupled to the center beam, the shadow frame body having a top surface, a bottom surface, and a plurality of side surfaces, a cavity is disposed in the top surface of the shadow frame body for receiving the center beam; one or more fastening mechanisms coupled with the center beam and the shadow frame body; and a cover plate, the cover plate disposed over the center beam and coupled to the shadow frame body.

In yet another embodiment, a shadow frame including a center beam with one or more surfaces for receiving one or more fastening mechanisms, the center beam disposed over a rest button and the rest button is coupled to a susceptor; a rectangular shadow frame body coupled to the center beam, the shadow frame body having a top surface, a bottom surface, and a plurality of side surfaces, the center beam is separable from the shadow frame body; a first mounting joint disposed in the top surface of the shadow frame body, comprising a cavity for receiving the center beam, the first mounting joint is fixed; a second mounting joint disposed in the top surface of the rectangular shadow frame body, comprising a cavity for receiving the center beam, the second mounting joint is fixed; one or more fastening mechanisms coupled with the center beam and the shadow frame body; and a ceramic cover plate, the ceramic cover plate disposed over the center beam and coupled to the shadow frame body, the ceramic cover plate is coupled to the rectangular shadow frame body via one or more second fastening mechanisms.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a cross sectional view of a PECVD chamber, according to one or more embodiments of the disclosure.

FIG. 2A is a schematic bottom view of a shadow frame having a center beam, according to one or more embodiments of the disclosure.

FIG. 2B is a schematic perspective view of a shadow frame having a center beam, according to one or more embodiments of the disclosure.

FIG. 3 is a schematic cross sectional view of a shadow frame having a center beam, according to one or more embodiments of the disclosure.

FIG. 4A is a schematic view of a mounting joint of a center beam for a shadow frame, according to one or more embodiments of the disclosure. FIG. 4B is a schematic cross sectional view of the mounting joint of the center beam for a shadow frame of FIG. 4A, according to one or more embodiments of the disclosure.

FIG. 5A is a schematic view of a mounting joint of a center beam for a shadow frame, according to one or more embodiments of the disclosure. FIG. 5B is a schematic cross sectional view of the mounting joint of the center beam for the shadow frame of FIG. 5A, according to one or more embodiments of the disclosure.

FIG. 6A is a schematic view of a shadow frame with a cover plate, according to one or more embodiments of the disclosure. FIG. 6B is a schematic cross sectional view of a shadow frame with a cover plate of FIG. 6A, according to one or more embodiments of the disclosure.

FIG. 7 is a schematic cross sectional view of a shadow frame engaged with the susceptor, according to one or more embodiments of the disclosure.

FIG. 8 is a schematic cross sectional view of a shadow frame engaged with the susceptor, according to one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclose generally relates to a shadow frame having a cross center beam for improved processing ability, manufacturability, and tolerance. In one embodiment, a shadow frame comprises a center beam with one or more surfaces for receiving one or more fastening mechanisms, a shadow frame body coupled to the center beam, the shadow frame body having a top surface, a bottom surface, and a plurality of side surfaces, the top surface having a cavity therein for receiving the center beam, and one or more fastening mechanisms coupled with the center beam and the shadow frame body.

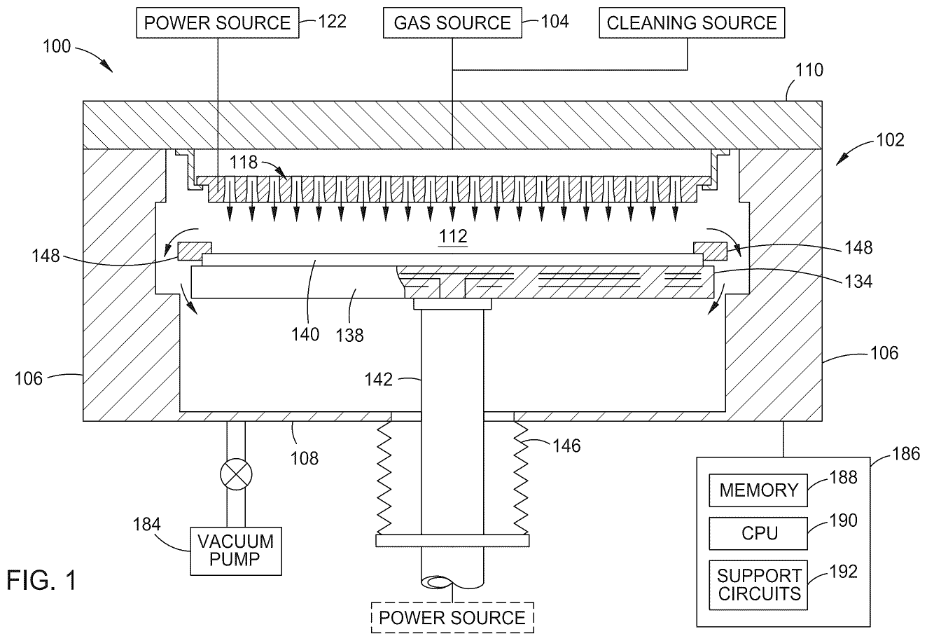

FIG. 1 illustrates a cross sectional view of a PECVD chamber, according to one or more embodiments of the disclosure. FIG. 1 is a schematic cross-sectional view of one embodiment of a PECVD system 100. It is to be understood that the subject matter may be practiced on other processing systems that introduce a gas into the chamber, including those processing systems produced by other manufacturers.

The system 100 may include a processing chamber 102 coupled to a gas source 104. The processing chamber 102 has walls 106 and a bottom 108 that partially define a process volume 112. The process volume 112 may be accessed through a port (not shown) in the walls 106 that facilitate movement of a substrate 140 into and out of the processing chamber 102. The walls 106 and bottom 108 may be fabricated from a unitary block of aluminum or other material compatible with processing. The walls 106 support a lid assembly 110. The processing chamber 102 may be evacuated by a vacuum pump 184.

A temperature controlled substrate support assembly 138 may be centrally disposed within the processing chamber 102. The support assembly 138 may support a substrate 140 during processing. The support assembly 138 may have a susceptor 134. The susceptor 134 supports the substrate 140. A stem 142 may be coupled to the lower side of the support assembly 138. The stem 142 couples the support assembly 138 to a lift system (not shown) that moves the support assembly 138 between an elevated processing position and a lowered position that facilitates substrate transfer to and from the processing chamber 102. The stem 142 additionally provides a conduit for electrical and thermocouple leads between the support assembly 138 and other components of the system 100.

A bellows 146 may be coupled between support assembly 138 (or the stem 142) and the bottom 108 of the processing chamber 102. The bellows 146 provides a vacuum seal between the process volume 112 and the atmosphere outside the processing chamber 102 while facilitating vertical movement of the support assembly 138. The support assembly 138 may be grounded such that RF power supplied by a power source 122 to a gas distribution plate assembly 118 positioned between the lid assembly 110 and substrate support assembly 138 (or other electrode positioned within or near the lid assembly of the chamber) may excite gases present in the process volume 112 between the support assembly 138 and the distribution plate assembly 118. The RF power from the power source 122 may be selected commensurate with the size of the substrate to drive the chemical vapor deposition process.

The support assembly 138 may additionally support a circumscribing shadow frame 148. The shadow frame 148 may prevent deposition at the edge of the substrate 140 and support assembly 138 so that the substrate 140 may not stick to the support assembly 138. As shown in FIG. 1, a controller 186 may interface with and control various components of the substrate processing system. The controller 186 may include a central processing unit (CPU) 190, support circuits 192 and a memory 188. The processing gas may enter into the chamber 102 from the gas source 104 and be exhausted out of the chamber 102 by a vacuum pump 184.

As will be discussed below, when the substrate 140 is placed on the susceptor 134, the susceptor 134 raises to meet the shadow frame 148 such that the shadow frame 148 is placed around the substrate 140 to cover the area on the susceptor 134 that is exposed to the processing gas in the processing chamber 102. To ensure the shadow frame 148 is properly aligned onto the susceptor, alignment inserts may be used. By placing the shadow frame 148 around the substrate 140, the deposition at the edge of the substrate 140 and the susceptor 134 may be reduced.

Currently, large sized shadow frames for large sized substrates often face issues relating to processing ability (e.g., deformity), manufacturability, and tight tolerances (e.g., flatness). For example, for double large size glass substrates (1310 millimeter (mm)×2290 mm or larger). Specifically, during substrate processing large shadow frames may deform due to the heat or other deforming factors in the processing chamber. These deformities of the shadow frame may cause gaps between the main body of the shadow frame and center bar, which may cause arcing. Thus, implementing a cross-center beam across the shadow frame reduces deformation of the shadow frame and helps to maintain the planar configuration of the shadow frame. As a result, arcing caused by any gaps between the shadow frame body and the center beam is avoided.

Additionally, by providing a cross-center beam that is separable from the main body of the shadow frame, manufacturability of the shadow frame increases. Manufacturing such large shadow frame presents issues since it is difficult to manufacture the shadow frame as one place, but by have the center beam separate but later coupled to the main body of the shadow frame, manufacturing costs are reduced.

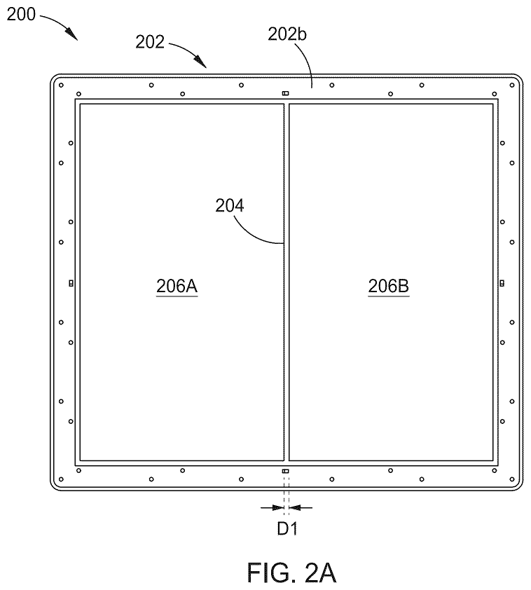

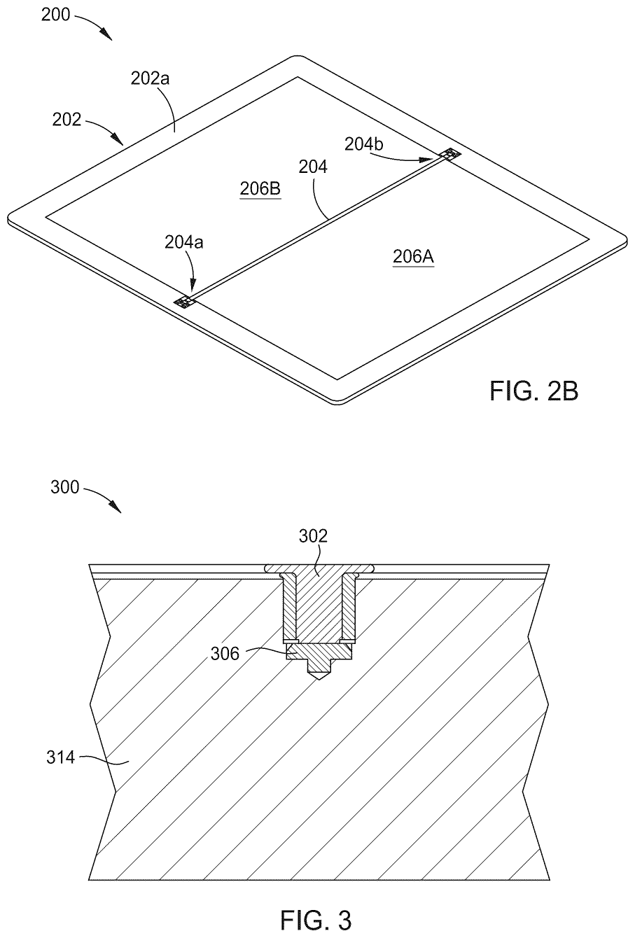

FIG. 2A is a schematic bottom view of a shadow frame 200 having a center beam, according to one or more embodiments of the disclosure. The shadow frame 200 comprises a main body 202, a center beam 204 (located at a midpoint), and openings 206A, 206B where the substrate (e.g., glass substrate) is located. In some embodiments, shadow frame 200 is implemented into a display CVD system having a Touch Screen Panel (TSP) chamber (e.g., a 65K TSP SF chamber) and double glass substrates on a susceptor in chamber. A shadow frame with a center beam, such as shadow frame 200, may be used for the double glass substrate process.

The main body 202 further comprises a top surface 202a (shown in FIG. 2B), a bottom surface 202b, and a plurality of side surfaces. The shadow frame 200 comprises a metal such as aluminum, or other ceramics such alumina (Al₂O₃). Other materials are also contemplated. In some embodiments, the center beam 204 creates a separation distance or gap (D1) between openings 206A and 206B between a range of about 20 millimeters (mm) to about 30 mm, such as 20 mm. The separation distance or gap (D1) created by center beam 204 protects the perimeters of the double substrates from RF plasma initiated arcing.

FIG. 2B is a schematic perspective view of a shadow frame 200 having a center beam, according to one or more embodiments of the disclosure. The shadow frame 200 comprises the main body 202, the center beam 204, and openings 206A, 206B where the substrate is located. The main body 202 further comprises a top surface 202a, a bottom surface 202b (shown in FIG. 2A), and a plurality of side surfaces. In some embodiments, center beam 204 is separable from the main body 202. The center beam 204 may be coupled to a top surface 202a of the main body 202 via fastening mechanisms, such as bolts or screws, at a first mounting joint 204a and a second mounting joint 204b. A first mounting joint 204a of the shadow frame 200 may be fixed, while a second mounting joint 204b of the shadow frame 200 may be free (e.g., not fixed) to compensate for thermal expansion of the shadow frame during processing.

FIG. 3 is a schematic cross sectional view of a shadow frame 300 having a center beam, according to one or more embodiments of the disclosure. The susceptor 314 (e.g., susceptor 134 of FIG. 1) may have a button 306 coupled thereto. The button 306 engages with the T-shaped center beam 302 (e.g., center beam 204 of FIGS. 2A and 2B) to align the shadow frame 300 with the susceptor 314. The button 306 may comprise an electrical insulating material, and/or a ceramic material.

One advantage of using ceramic material for the button 306 is that when there is constant heat applied to the substrate within the chamber, the button 306 made with ceramic material may not expand or contract due to the heat factor, thus when the button 306 is engaged with the T-shaped center beam 302, the size and shape of the button 306 may remain substantially constant, and the engagement between the button 306 and the T-shaped center beam 302 may remain tightly secured in place. Therefore, the alignment between the shadow frame 300 and the susceptor 314 may remain in uniform and proper position.

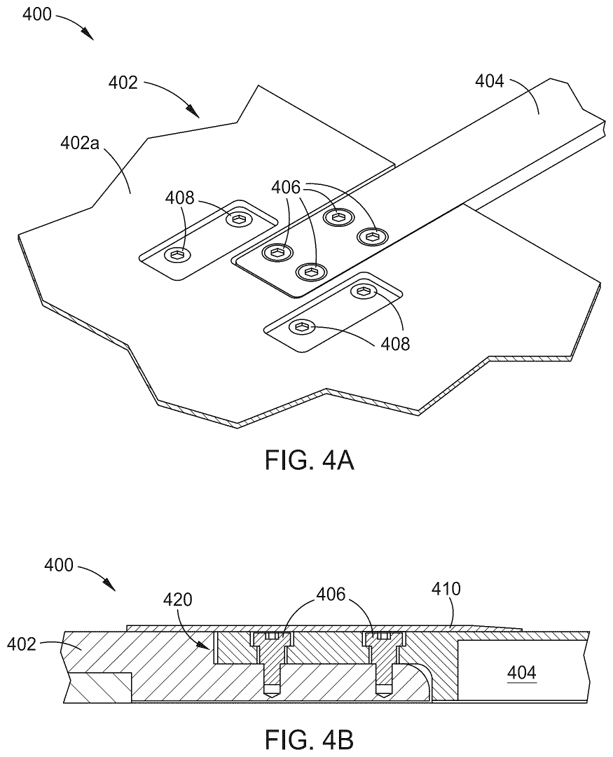

FIG. 4A is a schematic view of a mounting joint (e.g., first mounting joint 204a of FIG. 2B) of a center beam 404 for a shadow frame 400, according to one or more embodiments of the disclosure. Shadow frame 400 comprises a main body 402 and a center beam 404. The main body 402 may be main body 202 of FIGS. 2A and 2B. Center beam 404 may be center beam 204 of FIGS. 2A and 2B. The top surface 402a of main body 402 of shadow frame 400 includes a recess formed therein which the center beam 404 is disposed, such that the top surface 402a of the main body 402 is coplanar with the top surface of the center beam 404. The center beam is secured in place via fastening mechanisms 406. In some embodiments, the center beam 404 may be separated from the main body 402 via removal of the fastening mechanisms 406.

The fastening mechanisms 406 may comprise anodized aluminum shoulder screws and may optionally be low profile screws that are coplanar with, or below, the upper surface of the center beam 404. The center beam 404 may be coupled with the main body 402 of the shadow frame 400 via fastening mechanisms 406 on a surface adjacent to and substantially parallel to the surface on which a button (e.g., button 306 of FIG. 3) is coupled with a susceptor (e.g., susceptor 314 of FIG. 3). If the fastening mechanisms 406 were stripped, such as may occur with anodized fastening mechanisms, the fastening mechanisms 406 will be spaced from the susceptor and thus, arcing may be reduced. It is noted that though four fasteners (e.g., screws) are depicted, the fastening mechanism 406 may include any number of fasteners suitable for coupling the center beam 404 to the main body 402. Fastening mechanisms 408 may be placed substantially near the mounting joint of the center beam 404 to main body 402. Fastening mechanisms 408 may be used for coupling a cover plate (not shown) over center beam 404 to the main body 402 using additional fastening mechanisms.

FIG. 4B is a schematic cross sectional view of a mounting joint (e.g., first mounting joint 204a of FIG. 2B) of the center beam 404 for a shadow frame 400 of FIG. 4A, according to one or more embodiments of the disclosure. Fastening mechanisms 406 are used to couple the center beam 404 to the main body 402 of shadow frame 400. The main body 402 of the shadow frame 400 may receive the center beam 404 via a cavity 420 disposed in the main body 402. A cover plate 410 is disposed over a portion of the main body 402 where the fastening mechanisms 406 couple the center beam 404 to the main body 402 of the shadow frame 400. In some embodiments, cover plate 410 may be coupled to the main body 402, but over center beam 404 using fastening mechanisms 408. It is noted that though four fasteners (e.g., screws) are depicted, the fastening mechanism may include any number of fasteners suitable for coupling the cover plate 410 to the main body 402. The cover plate 410 prevents arcing around fastening mechanisms 408 and seams of the center beam 404 and shadow frame 400. Cover plate 410 may comprise ceramic, metal matrix composite (MMC), metal plate with coating (e.g., a ceramic coating using any coating method), or a combination thereof. Examples of coating the metal plate are plating, plasma spray coating, diffusion coating, etc.

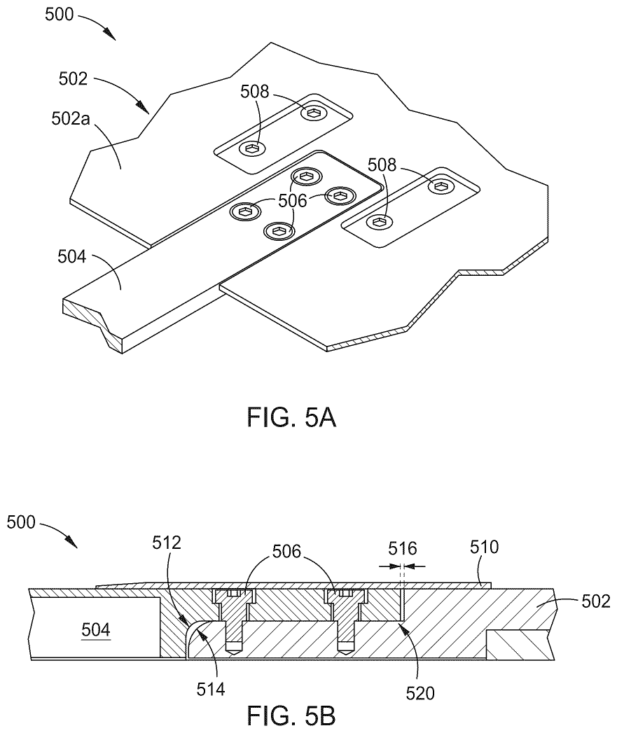

FIG. 5A is a schematic view of a mounting joint (e.g., second mounting joint 204b of FIG. 2B) of a center beam 504 for a shadow frame 500, according to one or more embodiments of the disclosure. Shadow frame 500 comprises a main body 502 and a center beam 504. Shadow frame 500 may be shadow frame 200 of FIGS. 2A and 2B and/or shadow frame 400 of FIGS. 4A and 4B. The main body 502 may be main body 202 of FIGS. 2A and 2B and/or main body 402 of FIGS. 4A and 4B. Center beam 504 may be center beam 204 of FIGS. 2A and 2B and/or center beam 404 of FIGS. 4A and 4B. The top surface 502a of main body 502 of shadow frame 500 is coupled to center beam 504 via fastening mechanisms 506. In some embodiments, the center beam 504 may be separated from the main body 502.

In some embodiments, the fastening mechanisms 506 may comprise anodized aluminum screws. In some embodiments, fastening mechanisms 506 may be low profile screws. The center beam 504 may be coupled with the main body 502 of the shadow frame 500 via fastening mechanisms 506 on a surface adjacent to and substantially parallel to the surface on which a button (e.g., button 306 of FIG. 3) is coupled with a susceptor (e.g., susceptor 314 of FIG. 3). If the fastening mechanisms 506 were stripped, such as may occur with anodized fastening mechanisms, the fastening mechanisms 506 will be spaced from the susceptor and thus, arcing may be reduced. It is noted that though four fasteners (e.g., screws) are depicted, the fastening mechanism may include any number of fasteners suitable for coupling the center beam 504 to the main body 502. Fastening mechanisms 508 may be placed substantially near the mounting joint of the center beam 504 to main body 502 for coupling a cover plate (not shown) over center beam 504 to the main body 502 using additional fastening mechanisms.

FIG. 5B is a schematic cross sectional view of the mounting joint (e.g., second mounting joint 204b of FIG. 2B) of the center beam 504 for the shadow frame 500 of FIG. 5A, according to one or more embodiments of the disclosure. Fastening mechanisms 506 are used to couple the center beam 504 to the main body 502 of shadow frame 500. The main body 502 of the shadow frame 500 may receive the center beam 504 via a cavity 520 disposed in the main body 502. A cover plate 510 may be disposed over a portion of the main body 502 where the fastening mechanisms 506 couple the center beam 504 to the main body 502 of the shadow frame 500. In some embodiments, cover plate 510 may be coupled to the main body 502, but over center beam 504 using fastening mechanisms 508. It is noted that though four fasteners (e.g., screws) are depicted, the fastening mechanism may include any number of fasteners suitable for coupling the cover plate 510 to the main body 502.

A bottom surface 512 of center beam 504 interfacing with a lip edge 514 of the main body 502 has a radius of a curve of about R.20. In some embodiments, the lip edge 514 of the main body 502 interfacing with a bottom surface 512 of center beam 504 has a radius of a curve of about R.30. In some embodiments, a gap 516 between an end surface of the center beam 504 and main body 502 is between a range of about 0.025 inches (in) to about 0.035 in, such as 0.030 in.

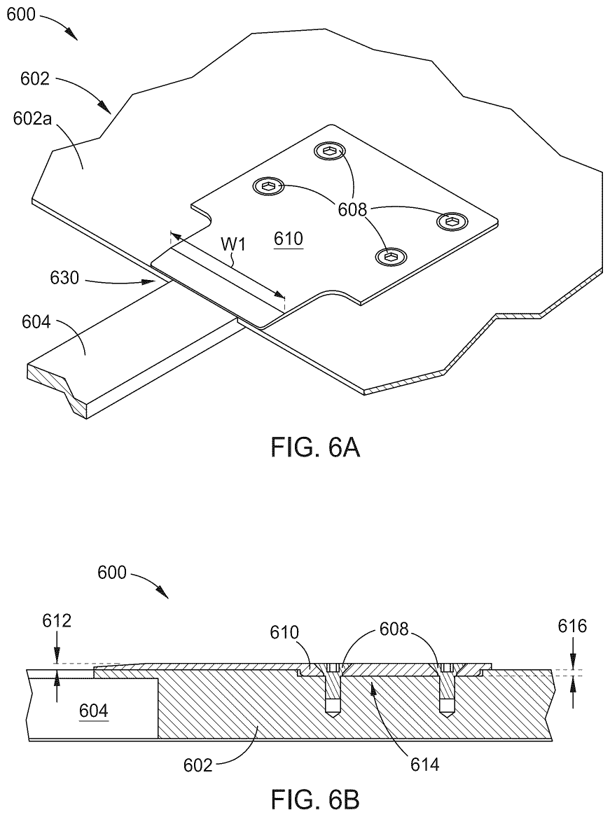

FIG. 6A is a schematic view of a shadow frame 600 with a cover plate 610, according to one or more embodiments of the disclosure. Shadow frame 600 comprises a main body 602 and a center beam 604. Shadow frame 600 may be shadow frame 200 of FIGS. 2A and 2B, shadow frame 400 of FIGS. 4A and 4B, and/or shadow frame 500 of FIGS. 5A and 5B. The main body 602 may be main body 202 of FIGS. 2A and 2B, main body 402 of FIGS. 4A and 4B, and/or main body 502 of FIGS. 5A and 5B. Center beam 604 may be center beam 204 of FIGS. 2A and 2B, center beam 404 of FIGS. 4A and 4B, and/or center beam 504 of FIGS. 5A and 5B. The top surface 602a of main body 602 of shadow frame 600 is coupled to center beam 604 via fastening mechanisms (not shown). In some embodiments, the center beam 604 may be separated from the main body 602. Width (W1) of an inner edge 630 of cover plate 610 should be minimized to reduce any impact on the deposition film thickness, which when affected creates a non-uniform deposition area. On the other hand, W1 should be wide enough to ensure robustness of the shadow frame 600 during handling and processing.

Cover plate 610 is disposed on a top surface of center beam 604, and is coupled to the top surface 602a of the main body 602 via fastening mechanisms 608. In some embodiments, which may be combined with other embodiments, the fastening mechanisms 608 are flat head screws. In some embodiments, fastening mechanisms 608 comprise alumina. It is noted that though four fasteners (e.g., screws) are depicted, the fastening mechanism may include any number of fasteners suitable for coupling the cover plate 610 to the main body 602.

FIG. 6B is a schematic cross sectional view of a shadow frame 600 with a cover plate 610 of FIG. 6A, according to one or more embodiments of the disclosure. Cover plate 610 is disposed on a top surface of center beam 604, and is coupled to the main body 602 via fastening mechanisms 608. The cover plate 610 comprises of alumina, but other materials are also contemplated. In some embodiments, the thickness 612 of the cover plate 610 is between a range of about 0.01 in to about 0.2 in, such as 0.060 in. In some embodiments, at least one portion of the top surface 602a of the main body 602 is recessed 614, where a depth 616 of the recess is about 0.080 in.

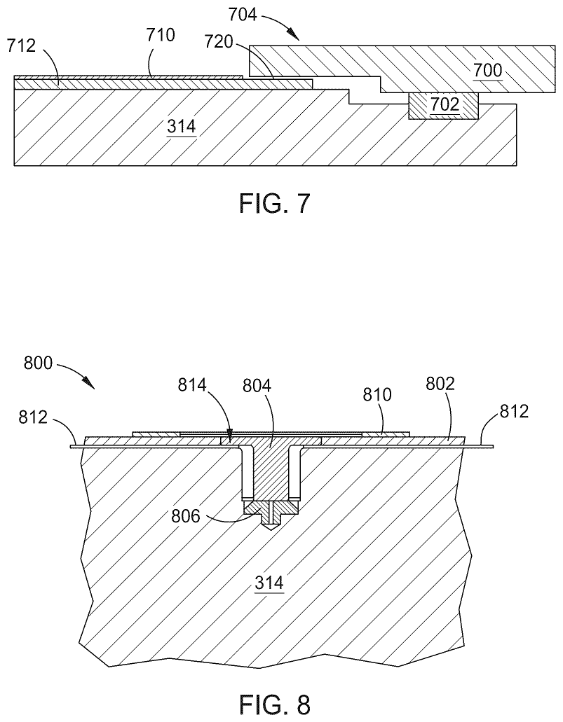

FIG. 7 is a schematic cross sectional view of a shadow frame 700 engaged with the susceptor 314, according to one or more embodiments of the disclosure. The shadow frame 700 may be coupled to a surface on which the button 702 is coupled with the susceptor 314. The button 702 may be used to couple the shadow frame 700 to the susceptor 314. The shadow frame 700 is shown spaced from the susceptor 314. The susceptor 314 may have a button 702 coupled thereto. The button 702 will engage with the center beam (not shown) to align the shadow frame 700 on the susceptor 314. In some embodiments, the button 702 may comprise an insulating material. In some embodiments, the button 702 may comprise a ceramic material.

In order to prevent deposition of particles (e.g., the deposition film 710) on the edge or on the underside of the substrate 712, a substrate holder may include an edge exclusion or shadow frame to prevent the processing of a perimeter portion 720 of the substrate surface (i.e., a perimeter portion of the upper surface of the substrate 712). As shown in FIG. 7, the shadow frame 700 includes a lip 704, which extends over the perimeter portion 720 of the substrate surface to prevent deposition of the deposition film 710 on the perimeter portion 720. By providing a shadow frame, processing gases and plasma are prevented from reaching the edge and backside of the substrate.

FIG. 8 is a schematic cross sectional view of a shadow frame 800 engaged with the susceptor, according to one or more embodiments of the disclosure. Shadow frame 800 comprises a main body 802 and a center beam 804. Shadow frame 800 may be shadow frame 200 of FIGS. 2A and 2B, shadow frame 400 of FIGS. 4A and 4B, shadow frame 500 of FIGS. 5A and 5B, shadow frame 600 of FIGS. 6A and 6B, and/or shadow frame 700 of FIG. 700. The main body 802 may be main body 202 of FIGS. 2A and 2B, main body 402 of FIGS. 4A and 4B, main body 502 of FIGS. 5A and 5B, and/or main body 602 of FIGS. 6A and 6B. Center beam 804 may be center beam 204 of FIGS. 2A and 2B, center beam 404 of FIGS. 4A and 4B, center beam 504 of FIGS. 5A and 5B, and/or center beam 604 of FIGS. 6A and 6B. Cover plate 810 may be the cover plate 410 of FIG. 4B, cover plate 510 of FIG. 5B, and/or cover plate 610 or FIG. 6B. The shadow frame 800 may be coupled on a surface on which the rest button 806 is coupled with the susceptor 314. The rest button 806 may be used to couple the shadow frame 800 to the susceptor 314.

In one or more examples, shadow frame 800 is spaced from the susceptor 314 (e.g., as shown in FIG. 7). In one or more example, shadow frame 800 includes a lip (e.g., lip 704 of FIG. 7), which extends over a perimeter portion of the substrate 812 to prevent deposition of a deposition film on the perimeter portion. In one or more examples, center beam 804 includes a lip 814 that also extends over the perimeter portion of the substrate 812.

In one embodiment, a shadow frame including a center beam with one or more surfaces for receiving one or more fastening mechanisms; a shadow frame body coupled to the center beam, the shadow frame body having a top surface, a bottom surface, and a plurality of side surfaces, a cavity is disposed in the top surface of the shadow frame body for receiving the center beam; and one or more fastening mechanisms coupled with the center beam and the shadow frame body.

The center beam is separable from the shadow frame body. The center beam comprises aluminum. The shadow frame body and the center beam are the same material. The center beam comprises alumina. The fastening mechanisms comprises at least one screw. The at least one screw is low profile. The at least one screw comprises of anodized aluminum. A lip edge of the shadow frame body interfacing with a bottom surface of center beam has a radius of a curve of R.30. A gap between an end surface of the center beam and shadow frame body is 0.030 inches or less.

In another embodiment, a shadow frame including a center beam with one or more surfaces for receiving one or more fastening mechanisms; a shadow frame body coupled to the center beam, the shadow frame body having a top surface, a bottom surface, and a plurality of side surfaces, a cavity is disposed in the top surface of the shadow frame body for receiving the center beam; one or more fastening mechanisms coupled with the center beam and the shadow frame body; and a cover plate, the cover plate disposed over the center beam and coupled to the shadow frame body.

The cover plate comprises ceramic. The cover plate further comprises alumina. The cover plate is coupled to the shadow frame body via one or more second fastening mechanisms. The one or more second fastening mechanisms comprises at least one screw. The at least one screw is a flat head screw comprising alumina.

In yet another embodiment, a shadow frame including a center beam with one or more surfaces for receiving one or more fastening mechanisms, the center beam disposed over a rest button and the rest button is coupled to a susceptor; a rectangular shadow frame body coupled to the center beam, the rectangular shadow frame body having a top surface, a bottom surface, and a plurality of side surfaces, the center beam is separable from the rectangular shadow frame body; a first mounting joint disposed in the top surface of the rectangular shadow frame body, comprising a cavity for receiving the center beam, the first mounting joint is fixed; a second mounting joint disposed in the top surface of the rectangular shadow frame body, comprising a cavity for receiving the center beam, the second mounting joint is fixed; one or more fastening mechanisms coupled with the center beam and the rectangular shadow frame body; and a ceramic cover plate, the ceramic cover plate disposed over the center beam and coupled to the shadow frame body, the ceramic cover plate is coupled to the rectangular shadow frame body via one or more second fastening mechanisms.

The ceramic cover plate further comprises alumina. A thickness of the ceramic cover plate is between 0.01 inches (in) and 0.2 in. The ceramic cover plate is coupled to the rectangular shadow frame body via one or more second fastening mechanisms, the one or more second fastening mechanisms comprises alumina.

While the foregoing is directed to embodiments of the present disclosure, other and further embodiments of the disclosure may be devised without departing from the basic scope thereof, and the scope thereof is determined by the claims that follow.

What is claimed is:

1. A shadow frame, comprising:
a center beam with one or more surfaces for receiving one or more fastening mechanisms;
a shadow frame body coupled to the center beam, the shadow frame body having a top surface, a bottom surface, and a plurality of side surfaces, a cavity is disposed in the top surface of the shadow frame body for receiving the center beam; and
one or more fastening mechanisms coupled with the center beam and the shadow frame body.

2. The shadow frame of claim 1, wherein the center beam is separable from the shadow frame body.

3. The shadow frame of claim 1, wherein the center beam comprises aluminum.

4. The shadow frame of claim 3, wherein the shadow frame body and the center beam are the same material.

5. The shadow frame of claim 1, wherein the center beam comprises alumina.

6. The shadow frame of claim 1, wherein the fastening mechanisms comprises at least one screw.

7. The shadow frame of claim 6, wherein the at least one screw is low-profile.

8. The shadow frame of claim 7, wherein the at least one screw comprises of anodized aluminum.

9. The shadow frame of claim 1, wherein a lip edge of the shadow frame body interfacing with a bottom surface of center beam has a radius of a curve of R.30.

10. The shadow frame of claim 1, wherein a gap between an end surface of the center beam and shadow frame body is 0.030 inches or less.

11. A shadow frame, comprising:
a center beam with one or more surfaces for receiving one or more fastening mechanisms;
a shadow frame body coupled to the center beam, the shadow frame body having a top surface, a bottom surface, and a plurality of side surfaces, a cavity is disposed in the top surface of the shadow frame body for receiving the center beam;
one or more fastening mechanisms coupled with the center beam and the shadow frame body; and
a cover plate, the cover plate disposed over the center beam and coupled to the shadow frame body.

12. The shadow frame of claim 11, wherein the cover plate comprises ceramic.

13. The shadow frame of claim 12, wherein the cover plate further comprises alumina.

14. The shadow frame of claim 11, wherein the cover plate is coupled to the shadow frame body via one or more second fastening mechanisms.

15. The shadow frame of claim 14, wherein the one or more second fastening mechanisms comprises at least one screw.

16. The shadow frame of claim 15, wherein the at least one screw is a flat head screw comprising alumina.

17. A shadow frame, comprising:
a center beam with one or more surfaces for receiving one or more fastening mechanisms, the center beam disposed over a rest button and the rest button is coupled to a susceptor;
a rectangular shadow frame body coupled to the center beam, the rectangular shadow frame body having a top surface, a bottom surface, and a plurality of side surfaces, the center beam is separable from the rectangular shadow frame body;
a first mounting joint disposed in the top surface of the rectangular shadow frame body, comprising a cavity for receiving the center beam, the first mounting joint is fixed;
a second mounting joint disposed in the top surface of the rectangular shadow frame body, comprising a cavity for receiving the center beam, the second mounting joint is fixed;
one or more fastening mechanisms coupled with the center beam and the rectangular shadow frame body; and
a ceramic cover plate, the ceramic cover plate disposed over the center beam and coupled to the rectangular shadow frame body, the ceramic cover plate is coupled to the rectangular shadow frame body via one or more second fastening mechanisms.

18. The shadow frame of claim 17, wherein the ceramic cover plate further comprises alumina.

19. The shadow frame of claim 17, wherein a thickness of the ceramic cover plate is between 0.01 inches (in) and 0.2 in.

20. The shadow frame of claim 17, wherein the ceramic cover plate is coupled to the rectangular shadow frame body via one or more second fastening mechanisms, the one or more second fastening mechanisms comprises alumina.
